(19) United States
(12) Patent Application Publication
(10) Pub. No.: US 2026/0043828 A1
(43) Pub. Date: Feb. 12, 2026

(54) TEST SOCKET ASSEMBLIES COOLED WITH GASEOUS FLUID FOR SEMICONDUCTOR INTEGRATED CIRCUITS

(71) Applicant: Smiths Interconnect Americas, Inc., Kansas City, KS (US)

(72) Inventors: Quynh Ngoc Nguyen, Fremont, CA (US); James Edward Spooner, Manteca, CA (US); Jiachun Zhou, Gilbert, AZ (US); Siang Huei Soh, Milpitas, CA (US)

(21) Appl. No.: 19/102,275

(22) PCT Filed: Aug. 8, 2023
(86) PCT No.: PCT/US23/29693

§ 371 Date: Feb. 7, 2025

Related U.S. Application Data
(60) Provisional application No. 63/396,389, filed on Aug. 9, 2022.

(51) Int. Cl. G01R 1/04

(52) U.S. Cl. CPC G01R 1/0458

(57) ABSTRACT

A socket assembly for a semiconductor integrated circuit (IC) chip is provided. The socket assembly includes a socket frame including a frame body defining a frame opening sized to receive a chip. The socket assembly also includes a socket cartridge including a cartridge body defining cavities each sized to receive a test probe therein. The socket assembly further includes a manifold assembly including a manifold defining a channel extending inside the manifold, a manifold inlet coupled with the manifold and sized to receive gaseous cooling fluid, and a manifold outlet coupled with the manifold and defining an aperture in fluid communication with the channel and the frame opening. The socket assembly defines a socket outlet in fluid communication with the frame opening, and the socket assembly defines a fluid path between the manifold inlet and the socket outlet.

### CROSS-REFERENCE TO RELATED APPLICATIONS

This application is a National Stage Entry of PCT/US2023/029693 filed on Aug. 8, 2023, which claims priority to U.S. Provisional Application Ser. No. 63/396,389, filed on Aug. 9, 2022, the contents of which are hereby incorporated by reference in their entirety.

### FIELD

The field of the disclosure relates generally to a test socket for semiconductor integrated circuits and, more specifically, a test system with a test socket assembly for testing semiconductor integrated circuit (IC) chips, where the test system is cooled by gaseous fluid.

### BACKGROUND

Semiconductor integrated circuit (IC) chips are produced in various packages, or chip configurations, and are produced in large quantities. Production of IC chips generally includes testing of the IC chips in a manner that simulates an end-user's application of those IC chips. One manner of testing IC chips is to connect each IC chip through a test socket assembly to a printed circuit board (PCB), or load board, that exercises various functionalities of the IC chip. The test socket assembly may be re-used to test many IC chips.

Operation of test socket assemblies may generate substantial amounts of heat. Further, known test socket assemblies may have disadvantages when it comes to reducing heat generation. Accordingly, improvements for cooling test socket assembles are desirable.

### BRIEF DESCRIPTION

In one aspect, a socket assembly for a semiconductor integrated circuit (IC) chip is provided. The socket assembly includes a socket frame including a frame body defining a frame opening sized to receive a semiconductor IC chip. The socket assembly also includes a socket cartridge including a cartridge body defining a plurality of cavities each sized to receive a test probe therein, the socket frame covering a portion of the socket cartridge and exposing the plurality of cavities at the frame opening. The socket assembly further includes a manifold assembly including a manifold defining a channel extending inside the manifold, a manifold inlet coupled with the manifold and sized to receive gaseous cooling fluid, and a manifold outlet coupled with the manifold and defining an aperture in fluid communication with the channel and the frame opening. The socket assembly defines a socket outlet in fluid communication with the frame opening, and the socket assembly defines a fluid path between the manifold inlet and the socket outlet.

In another aspect, a manifold assembly of a socket assembly for a semiconductor IC chip is provided. The manifold assembly includes a manifold defining a channel extending inside the manifold, a manifold inlet coupled with the manifold and sized to receive gaseous cooling fluid, and a manifold outlet coupled with the manifold and including an aperture in fluid communication with the channel and an exterior of the manifold assembly.

In one more aspect, a method of assembling a socket assembly for a semiconductor IC chip is provided. The method includes forming a socket frame including a frame body defining a frame opening sized to receive a semiconductor IC chip, the socket frame defining a frame inlet extending through the socket frame, the frame inlet in fluid communication with the frame opening. The method also includes forming a socket cartridge including a cartridge body defining a plurality of cavities each sized to receive a test probe therein and forming a manifold assembly. The manifold assembly includes a manifold defining a channel extending inside the manifold, a manifold inlet coupled with the manifold and sized to receive gaseous cooling fluid, and a manifold outlet coupled with the manifold and including an aperture in fluid communication with the channel. The method further includes coupling the manifold assembly with the socket frame by aligning the manifold outlet with the frame inlet such that the manifold outlet and the frame inlet are in fluid communication with one another. In addition, the method includes mounting the socket frame on the socket cartridge by covering a portion of the socket cartridge with the socket frame and exposing the plurality of cavities at the frame opening. The socket assembly defines a socket outlet in fluid communication with the frame opening of the socket frame, and defines a fluid path between the manifold inlet and the socket outlet.

### BRIEF DESCRIPTION OF THE DRAWINGS

FIG. 1 is an exploded view of a schematic diagram of an example test system;

FIG. 2A is a top perspective view of an example socket assembly in the test system shown in FIG. 1;

FIG. 2B is a bottom perspective view of the socket assembly shown in FIG. 2A;

FIG. 2C is an exploded view of the socket assembly shown in FIG. 2A;

FIG. 2D is a perspective view of a cross-section of the socket assembly shown in FIG. 2A taken along cross-sectional line 2D-2D as marked in FIG. 2A;

FIG. 2E is a partially transparent, perspective view of a manifold assembly of the socket assembly shown in FIG. 2A;

FIG. 2F is a cross-sectional view of the socket assembly shown in FIG. 2A along cross-sectional line 2F-2F as marked in FIG. 2A;

FIG. 2G is an enlarged view of a portion of the socket assembly shown in FIG. 2F;

FIG. 3A shows a profile of fluid flow;

FIG. 3B shows fluid flow paths; and

FIG. 4 is a flow diagram of a method of assembling the socket assembly shown in FIGS. 1-2G.

### DETAILED DESCRIPTION

The disclosure includes test socket assemblies and methods of improving heat transfer for test systems of semiconductor integrated circuit (IC) chips and socket assemblies using gaseous cooling fluid.

Consumer demands for next generation technologies such as high speed gaming, computer graphics, Internet of things (IoT), 5G, artificial intelligence (AI), deep learning, vehicle-to-vehicle communication, and self-driving vehicle create a need for high speed data transfer and processing technologies. High reliability testing is essential for such high speed, multi-function devices.

In testing IC chips, a fundamental component of a test system that enables testing of the IC chips is a test socket assembly for the IC chips, which may be re-used many times to test large quantities of IC chips. The test socket assembly connects, both electrically and mechanically, the IC chip to a printed circuit board (PCB) or a load board. The degree to which the test socket assembly may be re-used is quantified by how many “cycles” the test socket assembly can withstand without performance, e.g., signal performance, being degraded. Each time an IC chip is inserted, or set, into the test socket assembly is referred to as one cycle. Generally, over the course of many cycles, electrical and mechanical properties of the contacts and structures of the test socket assembly begin to degrade. One cause of the degradation is repeated heating and deformation of the test socket assembly from the heat generated by the IC chips during the testing, especially high performing IC chips. Such degradation eventually impacts integrity of the testing itself, at which point the test socket assembly reaches the end of useful life.

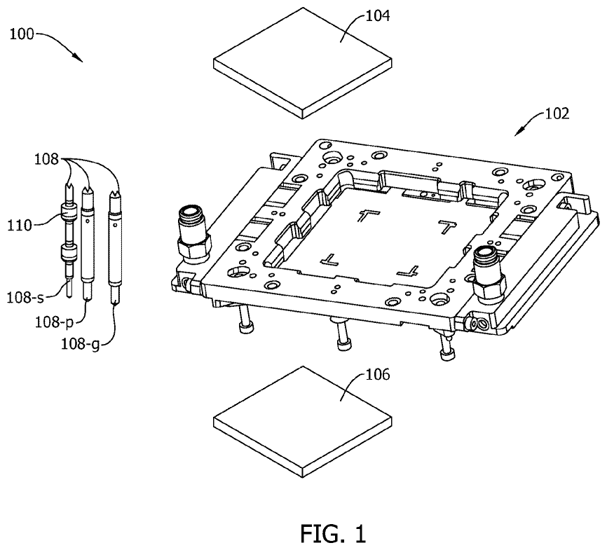

FIG. 1 is an exploded view of a schematic diagram of an example test system 100 that includes an example socket assembly 102, a semiconductor IC chip 104, and a PCB 106. IC chip 104 is to be tested with test system 100. PCB 106 includes test circuits. Socket assembly 102 provides electrical and mechanical connection between IC chip 104 and PCB 106. Test system 100 further include a plurality of probes 108. Probes 108 may include a ground probe 108-g, a signal probe 108-s, and a power probe 108-p. Probes 108 are placed in socket assembly 102 and used to establish electrical connections between IC chip 104 and PCB 106. Specifically, ground probe 108-g is connected to the ground. Signal probe 108-s transmits signals between IC chip 104 and PCB 106. Power probe 108-p is configured to be connected to a power supply. Power, grounding, and signals are provided through probes 108 from PCB board 106 to IC chip 104.

In operation, socket assembly 102 is mounted on PCB. To test IC chip 104, IC chip 104 is received in socket assembly 102 and placed in test system 100.

Socket assembly 102 serves as a re-usable interface for connecting many IC chips 104 to PCB 106. The high performance, e.g., high speeds, of IC chip 104 generate a large amount of heat. For example, the rate of heat transferred by a 63 millimeter (mm)×95 mm IC chip may reach 1.2 kilo-Watts (kW). However, socket assembly 102 generally needs to maintain high reliability without being adversely affected or overheated by the amount of heat generated during testing of IC chip 104.

Conventional socket frames for a socket assembly are fabricated from plastic, a thermally-nonconductive material. In such implementations, the IC chip is cooled by heat transfer through a heat sink in contact with the IC chip top surface (i.e., the surface of the IC chip that faces away from the test socket assembly). This cooling mechanism is effective in removing heat away from the IC chip top surface. However, as performance of IC chips increases, the amount of heat generated increases dramatically from the level of 100 Watts (W) to the level of 200 W, 300 W, even 900 W or above. Further, additional issues arise, where high heat is generated at contact points between the IC chip and the test socket assembly such as contact points between the IC chip and the probes. The high heat at the contact points is on the bottom side of the IC chip, which is the surface opposite the top surface of the IC chip and facing toward the test socket assembly. Heat sinks placed on the top surface of the IC chip may be insufficient or have increased difficulties in dissipating the high heat generated at the contact points. Dissipating that much heat efficiently and effectively is, therefore, a relatively-new problem that exists in reliably testing high-performing IC chips.

The high heat generated at the contact points degrades the performance and life of the test socket assembly. With repeated use of socket assembly 102 to test many IC chips 104, the large amount of heat may deform the socket assembly, affecting the electrical performance of conventional test systems and causing the system to be unable to transmit high-frequency signals. As a result, conventional test systems may have limited lifetime and unsatisfactory performance, especially with respect to high-frequency signals.

Systems and assemblies described herein provide solutions to the problems of dissipating heat from high performing IC chips during testing to ensure the testing quality and to prolong the life of the testing systems. Socket assemblies as disclosed herein are intended to keep test socket assemblies cooled by removing heat from the contact points between the test socket assembly and the IC chip using gaseous cooling fluid, thereby improving life of test sockets, reducing maintenance, and ultimately reducing down time of the test system. Gaseous cooling fluid is advantageous because flow paths are not limited to predefined fluid channels and gaseous cooling fluid may flow to be in contact or in proximity with the contact points.

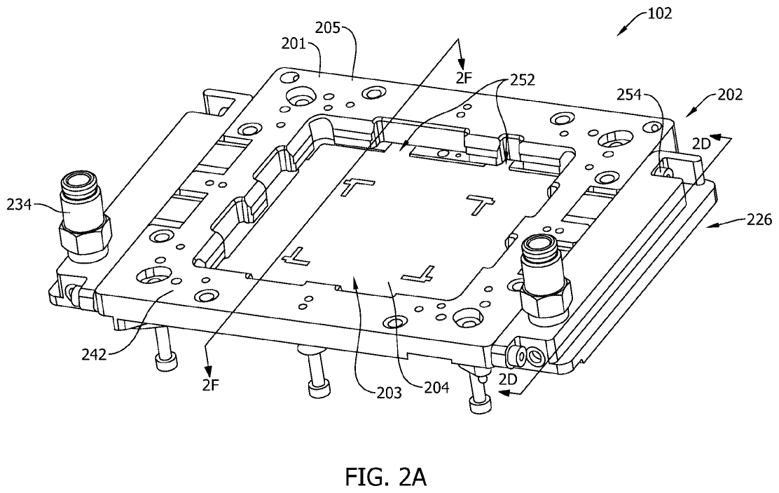

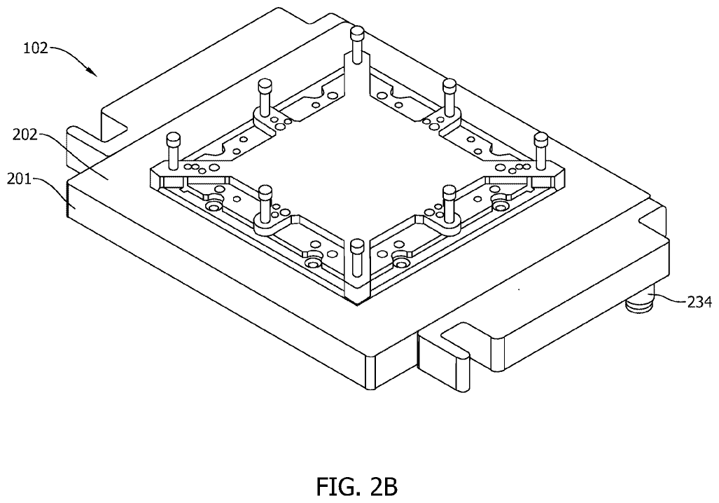

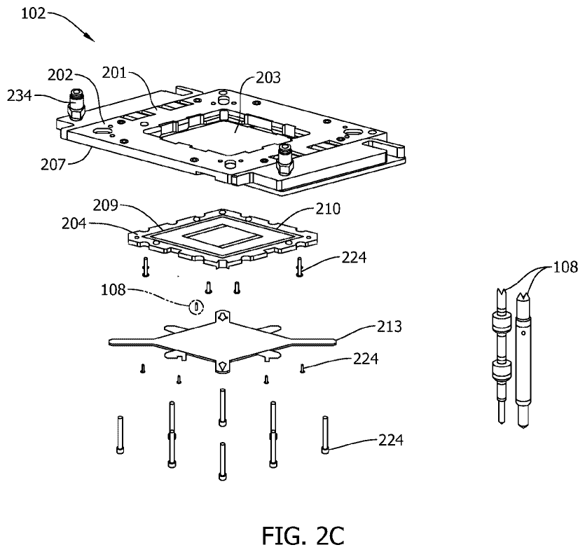

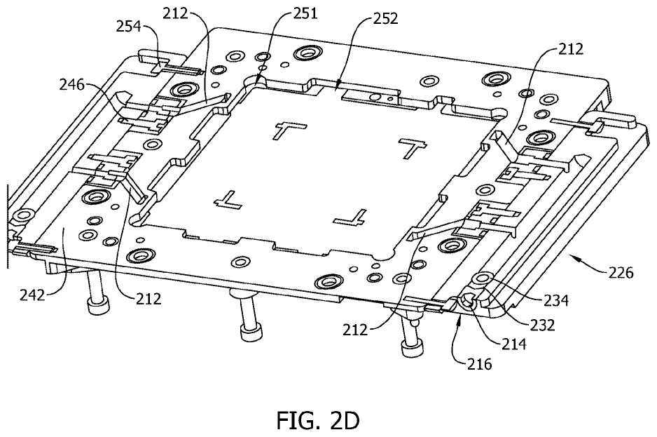

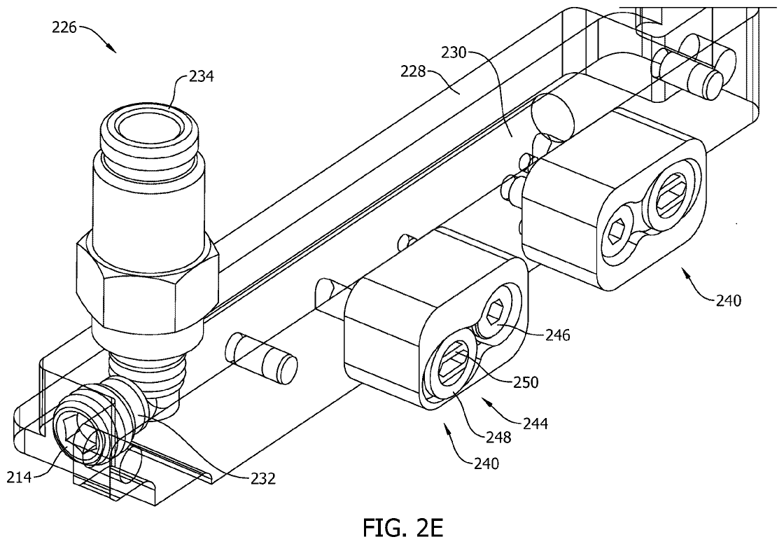

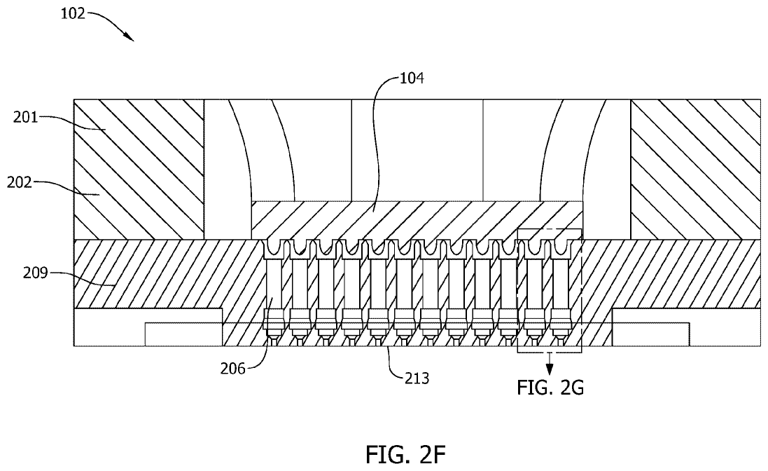

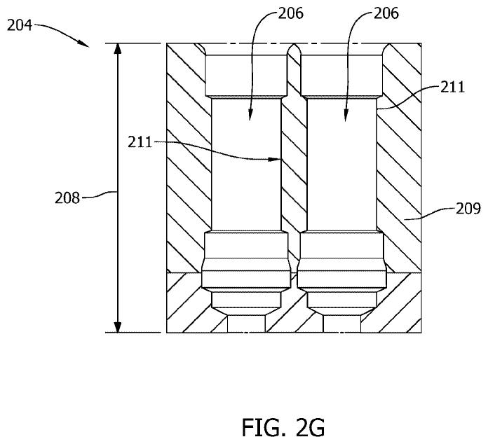

FIGS. 2A-2G show various views of an example socket assembly 102. FIG. 2A is a top perspective view of socket assembly 102. FIG. 2B is a bottom perspective view of socket assembly 102. FIG. 2C is an exploded view of socket assembly 102, where an enlarged view of probes 108 is also included. FIG. 2D is a perspective view of a cross section of socket assembly 102 taken along cross-sectional line 2D-2D as marked in FIG. 2A. FIG. 2E is a partially transparent, perspective view of a manifold assembly 226 of socket assembly 102. FIG. 2F is a cross-sectional view of socket assembly 102 along line 2F-2F as marked in FIG. 2A with IC chip 104 placed in socket assembly 102. FIG. 2G is an enlarged view of a portion of socket assembly 102 shown in FIG. 2F.

In the example embodiment, socket assembly 102 includes a socket frame 202 and a socket cartridge 204. In the depicted embodiment, socket frame 202 and socket cartridge 204 are separate pieces (see FIG. 2C). In some embodiments, socket frame 202 and socket cartridge 204 are fabricated as one single piece (i.e., only one piece). A single-piece socket assembly 102 may improve heat transfer through socket frame 202 and socket cartridge 204, as well as simplifying the process of manufacturing and assembling.

In the exemplary embodiment, socket frame 202 includes a frame body 201 (FIG. 2C). Frame body 201 defines an frame opening 203 sized to receive IC chip 104 therein. Frame body 201 includes frame borders 242 defining frame opening 203. Frame body 201 is metallic or is fabricated from metal, such as, but not limited to, aluminum, magnesium, titanium, zirconium, copper, iron, and/or an alloy thereof, such as aluminum 5053. Metallic frame body 201 may improve heat transfer. Socket frame 202 may further include an insulation layer 205 (FIG. 2A) positioned at the surface of frame body 201. Insulation layer 205 of socket frame 202 may be an anodic film, such as aluminum oxide, that is generated on the metal by an anodizing process and is electrically non-conductive. The insulation layer may be coated with a polytetrafluoroethylene (PTFE) coating. In some embodiments, parts of frame body 201 do not include insulation layer 205. For example, a side 207 or part of side 207 of frame body 201 that faces and mates with socket cartridge 204 does not have insulation layer 205 by removing insulation layer 205 or not ever being coated with insulation layer 205. Without the insulation layer at side 207, the thermal transmission between socket frame 202 and other parts of test system 100 such as socket cartridge 204 and IC chip 104 may be improved. The remaining surface of socket frame 202 is coated with insulation layer 205 to limit short-circuiting. In some embodiments, frame body 201 is not metallic, but is instead fabricated from non-metallic material or material that is not metallic, such as, but not limited to, plastic.

In the example embodiment, socket cartridge 204 includes a cartridge body 209 (FIGS. 2C, 2F, and 2G). Cartridge body 209 is metallic or is fabricated from metal, such as, but not limited to, aluminum, magnesium, titanium, zirconium, copper, iron, and/or an alloy thereof. Metallic cartridge body 209 improves heat transfer. Cartridge body 209 and frame body 201 may be fabricated from different types of metal or alloy. Cartridge body 209 defines a plurality of cavities 206 disposed through thickness 208 of socket cartridge 204 (FIG. 2G). Each of cavities 206 is sized to receive probe 108 therein. Cavity 206 may be a ground cavity 206 configured to receive a ground probe 108-g therein (see FIG. 1). Cavity 206 may be a signal cavity 206, which is configured to receive a signal probe 108-s therein. Cavity 206 may also be a power cavity 206, which is configured to receive a power probe 108-p therein. Socket cartridge 204 includes an insulation layer 211 along the surface of cavities 206 (FIG. 2G). Insulation layer 211 may be an anodic film, such as aluminum oxide, which is generated on the metal by an anodizing process and is electrically non-conductive. The insulation layer may be coated with a PTFE coating. Insulation layer 211 limits probes 108 from contacting each other to avoid an electrical short and limits probes 108 from contacting metallic socket cartridge 204. In some embodiments, ground cavity 206 does not have insulation layer 211 and/or has conductive material such as gold, copper, nickel, or another conductive material that is not easily oxidized, applied to the surface of ground cavity 206 such that oxidation between ground probe 108-g and cartridge body 209 is discouraged. As such, electrical performance and thermal conductivity of test system 100 may be improved. In some embodiments, signal probe 108-s includes an insulation ring 110 (see FIG. 1). Signal cavity 206 may not include an insulation layer 211, also improving the thermal performance of test system 100 without signal probe 108-s being electrically connected with socket cartridge 204. In other embodiments, a side 210 (FIG. 2C) of cartridge body 209 does not have insulation layer 211, improving the thermal performance of test system 100. When assembling socket cartridge 204 with socket frame 202, side 210 of socket cartridge 204 and side 207 of socket frame 202 face one another. In some embodiments, thermal grease or thermal paste (not shown) may be applied to side 207 of socket frame 202, side 210 of socket cartridge 204, or both. The thermal grease eliminates air gaps or spaces, which acts as thermal insulation, between sides 207, 210, thereby facilitating improving heat transfer and dissipation.

In the example embodiment, socket cartridge 204 further includes a cartridge bottom 213 (FIGS. 2C and 2F) used to retain probes 108 in place. Cavities 206 are provided through cartridge bottom 213 for probes 108 to be placed in cavities 206 and to be electrically connected with PCB board 106. Cavities 206 for signal probes 108-s include insulation material similar to the material of insulation ring 110.

In some embodiments, cartridge body 209 and/or cartridge bottom 213 is fabricated from a non-metallic material, such as, but not limited to, plastic. Using a non-metallic cartridge body and/or cartridge bottom provides improved electrical insulation.

To assemble socket assembly 102, socket frame 202 is placed over socket cartridge 204 such that frame opening 203 of socket frame 202 exposes cavities 206 of socket cartridge 204 for probes 108 to be placed in cavities 206 and for IC chip 104 to be placed in frame opening 203 and to be electrically connected with probes 108. Socket frame 202 and socket cartridge 204 may be coupled together using one or more fasteners 224, such as screws, nuts, or bolts.

With the application of metallic socket frame body 201 and metallic cartridge body 209 and mechanisms of improved heat transfer as described above, socket frame 202 and socket cartridge 204 may still not adequately dissipate the large amount of heat generated from operation of high functioning IC chips 104 during testing, especially the high heat generated at the contact points between IC chips 104 and probes 108. Additional heat sinks conventionally attached to IC chip 104 or socket assembly 102 may also fail to effectively dissipate the high heat generated at the contact points. The un-dissipated high heat generated at the contact points would degrade performance and shorten the life of socket assembly 102.

The socket assemblies disclosed herein incorporate fluid cooling to dissipate the high heat. In the example embodiment, socket assembly 102 further includes a manifold assembly 226 (FIG. 2E). Manifold assembly 226 includes a manifold 228 that defines a channel 230 positioned inside manifold 228. Channel 230 is positioned in the interior of manifold 228 and transversely extends through manifold 228. Channel 230 may be formed by drilling into manifold 228 starting from the exterior of manifold 228. Manifold assembly 226 may further include a plug 214 and/or an O-ring 232 to restrict fluid from coming out of a drill entry 216. Alternatively, channel 230 may be formed in manifold 228 by a manufacturing process of manifold 228, such as deforming, molding, or casting, during the manufacturing of manifold 228. Manifold 228 may be fabricated from metallic or non-metallic material.

In the example embodiment, manifold assembly 226 further includes a manifold inlet 234 sized to receive gaseous cooling fluid. In the depicted embodiment, manifold inlet 234 is coupled with manifold 228 at an angle with channel 230. In some embodiments, manifold inlet 234 is coupled with channel 230 along the longitudinal axis or the length direction of channel 230. Manifold inlet 234 may be coupled with manifold 228 at the location where plug 214 and/or O-ring 232 is by replacing plug 214 and/or O-ring 232 with manifold inlet 234, saving costs in parts and improving fluid flow. In some embodiments, manifold inlet 234 is formed integrally or as one single piece with manifold 228.

In the example embodiment, manifold assembly 226 further includes a manifold outlet 240. Manifold outlet 240 defines an aperture 244. Manifold outlet 240 may define another aperture sized to receive a fastener 246 therethrough to couple manifold outlet 240 with manifold 228. In some embodiments, manifold outlet 240 may be formed integrally or as one single piece with manifold 228. Manifold outlet 240 may further include an outlet ring 248 positioned at an end of aperture 244. The location of outlet ring 248 at the end of aperture 244 may be adjusted to control a clearance area on the socket frame 202 or the area on socket assembly 102 where manifold assembly 226 is mounted to. Outlet ring 248 may be adjusted up, down, left, and/or right. Manifold outlet 240 may include a lattice 250 that positioned at the end of aperture 244, interior to outlet ring 248. Lattice 250 reduces a path area, thereby increasing air pressure for an increased distance to be covered by the cooling fluid. Lattice 250 may be angled such that the spray pattern angle of the cooling fluid is increased for the cooling fluid to cover increased area. Manifold assembly 226 may include a plurality of manifold outlets 240 distributed along the length of channel 230.

In operation, when manifold inlet 234 and manifold outlet 240 are coupled with manifold 228, fluid flows into manifold assembly 226 from manifold inlet 234, through channel 230, and out of manifold assembly 226 via manifold outlets 240.

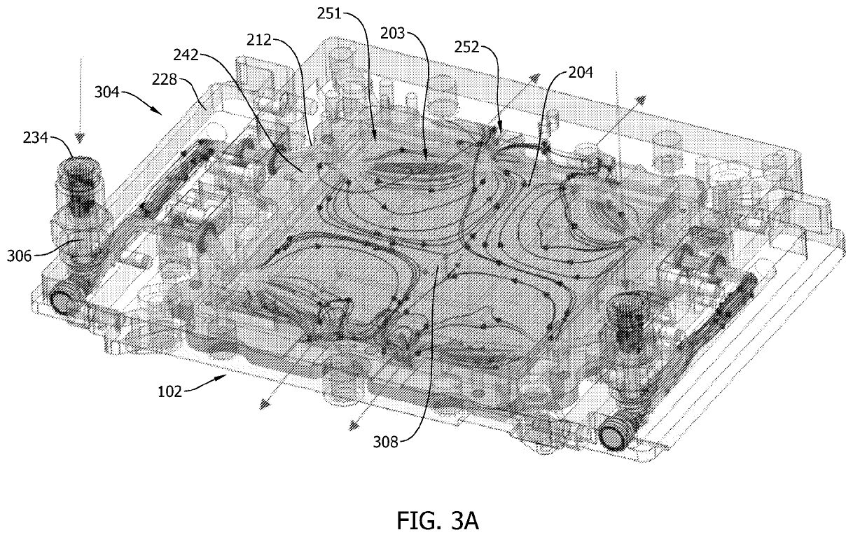

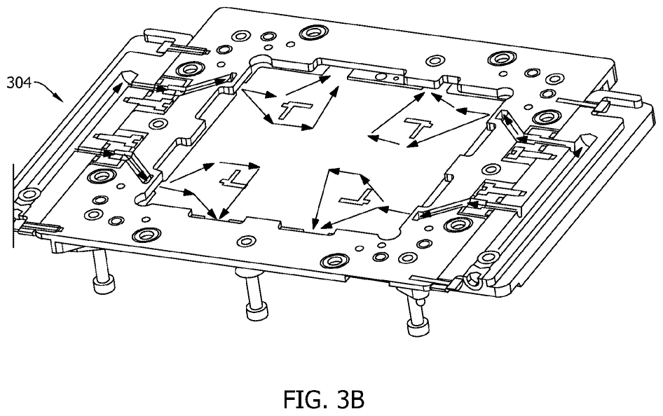

In the example embodiment, socket frame 202 of socket assembly 102 includes frame inlets 212. Frame inlets 212 may be channels defined through and inside frame border 242 of socket frame 202 (FIG. 2D, also see FIGS. 3A and 3B described later). Frame inlets 212 are positioned in the interior of frame body 201 and transversely positioned through frame body 201. Frame inlets 212 may be at an angle with frame border 242 and angled toward a corner 251 of frame opening 203. Frame inlet 212 in socket frame 202 may be formed by drilling into socket frame 202 starting from the exterior of socket frame 202. Alternatively, frame inlets 212 may be formed in frame body 201 by a manufacturing process, such as deforming or casting, during the manufacturing of frame body 201. Socket frame 202 and socket cartridge 204 may define an socket outlet 252. Socket outlet 252 may be a gap between socket frame 202 and socket cartridge 204. Socket outlets 252 may be positioned at multiple locations of socket assembly 102.

In operation, manifold assembly 226 is coupled with socket frame 202 via fasteners 254 such that manifold outlets 240 are in fluid communication with frame inlets 212. Fluid flows from manifold assembly 226 through manifold outlets to frame inlets 212 and into frame opening 203, cooling IC chips 104 positioned therein. In the depicted embodiment, manifold assembly 226 is positioned along frame border 242 of socket frame 202. Manifold assembly 226 may be positioned on or below frame border 242 of the socket frame 202. In some embodiments, manifold assembly 226 may be coupled with socket assembly 102 at other parts of socket assembly, such as a lid frame or a docking plate of socket assembly.

The flow rate of the cooling fluid is determined by the cooling need of test system 100 and may be adjusted by a cooling system (not shown) coupled to manifold inlet 234. Cooling fluid is gaseous. Example cooling fluid is dry air or dehumidified air, dry ice in the gaseous phase, or vaporized liquid nitrogen. Using dry ice in a gaseous phase or vaporized liquid nitrogen is advantageous because of the reduced temperature, as compared to dry air. In operation, dry ice in a gaseous phase or vaporized liquid nitrogen may be circulated from dry ice in a solid phase or liquid nitrogen to test system 100 via the cooling system.

In operation, socket assembly 102 is connected with the cooling system through manifold inlet 234. The cooling system pumps the cooling fluid in and cools socket assembly 102 and test system 100. The cooling fluid carries heat away from test system 100. In some embodiments, frame body 201 of socket frame 202 and cartridge body 209 of socket cartridge 204 are metallic and thermally conductive. Heat generated from IC chip 104, probes 108, and PCB 106 are transmitted to socket frame 202 and socket cartridge 204, which then transfer out through the cooling fluid circulating in the fluid paths.

The system and assemblies described herein may be used to effectively dissipate heat generated in testing high-performing IC chips when socket frame 202 and/or socket cartridge 204 is fabricated from a non-metallic material. Although non-metallic material has a much lower thermal conductivity than metal material, gaseous fluid flows in proximity to or in contact with contact points between IC chips 104 and socket cartridge 204 and other components in test system 100, carrying heat away from IC chips 104 and socket assembly 102.

Accordingly, heat is effectively dissipated, and the performance of IC chip 104 and socket assembly 102 remains consistent and unaffected by the large amount of heat and repeated use.

Manifold assemblies 226 described herein may be retrofit with existing test system 100 or socket assemblies 102 by coupling manifold assemblies 226 to socket assembly 102 or other parts of test system 100. For example, frame inlets 212 may be drilled in frame borders 242 of socket assembly 102 and coupling manifold assembly 226 with socket frame 202 such that manifold assembly 226 is in fluid communication with socket frame 202 at frame inlets 212. Alternatively, manifold assembly 226 may be installed on other parts of test system 100, such as a lid frame or a docking plate, for cooling fluid to flow into frame opening 203. Providing improved heat dissipation through retrofitting saves costs in parts and manufacturing.

FIGS. 3A and 3B show fluid flow in socket assembly 102. FIG. 3A shows fluid flow profile 302. FIG. 3B shows fluid paths 304. Fluid flow profile 302 and fluid paths 304 are based on simulated data. In fluid flow profile 302, lighter lines indicate lower temperatures. As shown, cooling fluid 306 flows into manifold 228 from manifold inlet 234. Cooling fluid 306 then flows through frame inlet 212 and into frame opening 203. Cooling fluid 306 circulates around and cooling IC chips 104, exiting from socket assembly 102 at socket outlet 252, carrying heat away from IC chips 104 and socket cartridge 204. Cooling fluid 306 flows on and/or above the top surface of socket cartridge 204. Cooling fluid 306 may also flow in areas between socket cartridge 204 and cartridge bottom 213 (see FIG. 2C). Frame inlets 212 are angled toward corners 251 of frame opening 203 to cover areas around IC chips. At least some of frame inlets 212 are positioned proximate corners 251. In operation, the parameters of socket assembly 102 and test system 100 may be adjusted based on simulated fluid flow. For example, a center 308 of frame opening 203 may have reduced fluid flow based on the simulation. Pressure of cooling fluid and/or dimensions of manifold inlets 234 may be adjusted. Angles of frame inlets 212 may also be adjusted. Additional frame inlets 212 may be included and positioned proximate a middle point between adjacent corners 251 such that the cooling fluid is directed toward center 308 of frame opening 203. In the depicted embodiment, two manifold assemblies 226 are positioned along two opposing frame borders 242 of socket frame 202. The number, shapes, positions of manifold assemblies 226 may be adjusted. For example, manifold assemblies 226 may be curved or multiple manifold assemblies may be used to surround corners 251 of frame opening 203, leaving socket outlets 252 open and in fluid communication with the exterior of test system 100.

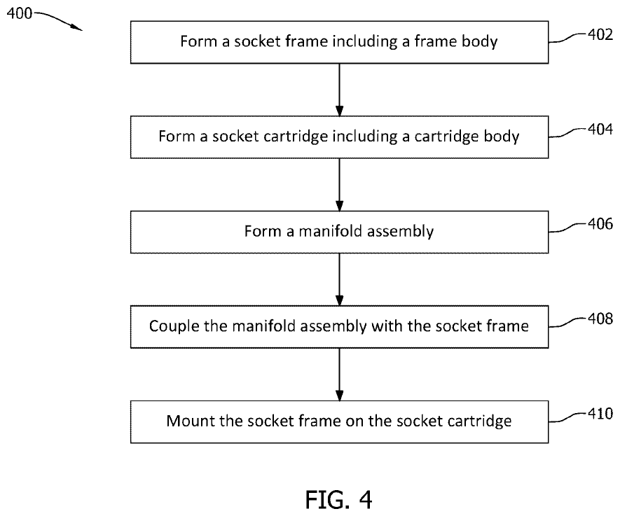

FIG. 4 is a flow chart of an example method 400 of assembling a socket assembly for an IC chip. The socket assembly may be socket assembly 102 disclosed above. In the example embodiment, method 400 includes forming 402 a socket frame including a frame body that defines a frame opening sized to receive the IC chip. The socket frame includes a frame inlet positioned through and inside the socket frame, the frame inlet being in fluid communication with the frame opening. Method 400 further includes forming 404 a socket cartridge including a cartridge body that defines a plurality of cavities each sized to receive a test probe therein. Method 400 also includes forming 406 a manifold assembly. The manifold assembly may be manifold assembly 226 disclosed above. Further, method 400 includes coupling 408 the manifold assembly with the socket frame by aligning the manifold outlet with the frame inlet such that the manifold outlet and the frame inlet are in fluid communication with one another. Method 400 also includes mounting 410 the socket frame on the socket cartridge by covering a portion of the socket cartridge and exposing the plurality of cavities at the opening.

The technical effects of the systems, apparatuses, and methods described herein may include: (a) improving heat transfer in a testing system of high-performing IC chips using gaseous cooling fluid; and (b) a retrofit manifold assembly used to improve heat dissipation in existing socket assemblies.

In the foregoing specification and the claims that follow, a number of terms are referenced that have the following meanings.

As used herein, an element or step recited in the singular and preceded with the word “a” or “an” should be understood as not excluding plural elements or steps, unless such exclusion is explicitly recited. Furthermore, references to “example implementation” or “one implementation” of the present disclosure are not intended to be interpreted as excluding the existence of additional implementations that also incorporate the recited features.

“Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. Here, and throughout the specification and claims, range limitations may be combined or interchanged. Such ranges are identified and include all the sub-ranges contained therein unless context or language indicates otherwise.

Disjunctive language such as the phrase “at least one of X, Y, or Z,” unless specifically stated otherwise, is generally understood within the context as used to state that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

The systems and methods described herein are not limited to the specific embodiments described herein, but rather, components of the systems and/or steps of the methods may be utilized independently and separately from other components and/or steps described herein.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

This written description uses examples to provide details on the disclosure, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A socket assembly for a semiconductor integrated circuit (IC) chip, said socket assembly comprising:
a socket frame comprising a frame body defining a frame opening sized to receive a semiconductor IC chip;
a socket cartridge comprising a cartridge body defining a plurality of cavities each sized to receive a test probe therein, said socket frame covering a portion of said socket cartridge and exposing the plurality of cavities at the frame opening; and
a manifold assembly comprising:
a manifold defining a channel extending inside said manifold;
a manifold inlet coupled with said manifold and sized to receive gaseous cooling fluid; and
a manifold outlet coupled with said manifold and defining an aperture in fluid communication with the channel and the frame opening,
wherein said socket assembly defines a socket outlet in fluid communication with the frame opening, and said socket assembly defines a fluid path between said manifold inlet and the socket outlet.

2. The socket assembly of claim 1, wherein said socket frame defines a frame inlet extending through said socket frame, the frame inlet in fluid communication with the frame opening, said manifold assembly coupled with said socket frame, and the aperture of said manifold outlet in fluid communication with the frame inlet.

3. The socket assembly of claim 2, wherein the frame inlet is angled towards a corner of the frame opening.

4. The socket assembly of claim 2, wherein the frame inlet is positioned proximate a corner of the frame opening.

5. The socket assembly of claim 1, wherein the gaseous cooling fluid is dehumidified air.

6. The socket assembly of claim 1, wherein the gaseous cooling fluid is dry ice in a gaseous phase and/or vaporized liquid nitrogen.

7. The socket assembly of claim 1, wherein said manifold inlet is positioned along a longitudinal axis of the channel.

8. The socket assembly of claim 1, wherein said manifold outlet further comprises a lattice positioned at an end of the aperture.

9. The socket assembly of claim 1, wherein said manifold outlet further comprises an adjustable outlet ring positioned at an end of the aperture.

10. A manifold assembly of a socket assembly for a semiconductor integrated circuit (IC) chip, said manifold assembly comprising:
a manifold defining a channel extending inside said manifold;
a manifold inlet coupled with said manifold and sized to receive gaseous cooling fluid; and
a manifold outlet coupled with said manifold and including an aperture in fluid communication with the channel and an exterior of said manifold assembly.

11. The manifold assembly of claim 10, wherein the gaseous cooling fluid is dehumidified air, dry ice in a gaseous phase, and/or vaporized liquid nitrogen.

12. The manifold assembly of claim 10, wherein said manifold outlet further comprises a lattice positioned at an end of the aperture.

13. The manifold assembly of claim 10, wherein said manifold outlet further comprises an adjustable ring positioned at an end of the aperture.

14. The manifold assembly of claim 10, wherein said manifold inlet is positioned along a longitudinal axis of the channel.

15. A method of assembling a socket assembly for a semiconductor integrated circuit (IC) chip, said method comprising:
forming a socket frame including a frame body defining a frame opening sized to receive a semiconductor IC chip, the socket frame defining a frame inlet extending through the socket frame, the frame inlet in fluid communication with the frame opening;
forming a socket cartridge including a cartridge body defining a plurality of cavities each sized to receive a test probe therein;
forming a manifold assembly that includes:
a manifold defining a channel extending inside the manifold;
a manifold inlet coupled with the manifold and sized to receive gaseous cooling fluid; and
a manifold outlet coupled with the manifold and including an aperture in fluid communication with the channel;
coupling the manifold assembly with the socket frame by aligning the manifold outlet with the frame inlet such that the manifold outlet and the frame inlet are in fluid communication with one another; and
mounting the socket frame on the socket cartridge by covering a portion of the socket cartridge with the socket frame and exposing the plurality of cavities at the frame opening,
wherein the socket assembly defines a socket outlet in fluid communication with the frame opening of the socket frame, and defines a fluid path between the manifold inlet and the socket outlet.

16. The method of claim 15, wherein forming a manifold assembly further comprises positioning the manifold inlet along a longitudinal axis of the channel.

17. The method of claim 15, wherein forming a socket frame further comprises positioning the frame inlet to be angled towards a corner of the frame opening.

18. The method of claim 15, wherein forming a socket frame further comprises positioning the frame inlet proximate a corner of the frame opening.

19. The method of claim 15, further comprising:
simulating fluid flow in the socket assembly; and
optimizing a parameter of the socket assembly based on the simulated fluid flow.

20. The method of claim 15, wherein forming a manifold assembly further comprises forming the manifold assembly that includes a lattice and/or an adjustable ring positioned at an end of the aperture.
